(19) United States
(12) Patent Application Publication
(10) Pub. No.: US 2009/0017401 A1
(43) Pub. Date: Jan. 15, 2009

(54) METHOD OF FORMING MICROPATTERN

(76) Inventor: Shinichi ITO, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/170,483

(22) Filed: Jul. 10, 2008

(30) Foreign Application Priority Data
Jul. 10, 2007 (JP) 2007-181318
Jul. 8, 2008 (JP) 2008-177495

(51) Int. Cl. G03F 7/20

(52) U.S. Cl. 430/323; 430/322

(57) ABSTRACT

A resist film provided on one major surface of a process target substrate is patterned to form a resist pattern. A solubilization process is carried out on the resist film remaining in a space portion of the resist pattern to make the resist film easily soluble in a liquid for removing the remaining resist film. Then, the liquid is supplied to the remaining resist film.

### CROSS-REFERENCE TO RELATED APPLICATIONS

This application is based upon and claims the benefit of priority from prior Japanese Patent Applications No. 2007-181318, filed Jul. 10, 2007; and No. 2008-177495, filed Jul. 8, 2008, the entire contents of both of which are incorporated herein by reference.

### BACKGROUND OF THE INVENTION

1. Field of the Invention

The present invention relates to a pattern formation method for a lithography step for forming a semiconductor device, and more specifically, to a pattern formation method enabling formation of fine patterns.

2. Description of the Related Art

Various pattern formation techniques have been proposed to form patterns to desired shapes in a lithography step. In particular, with significantly increasing miniaturization and integration of various electronic devices including semiconductor devices and liquid crystal devices, pattern formation techniques have recently been required which enable finer patterns to be formed to desired shapes. For example, pattern formation techniques have been required which enable formation, to desired shapes, of fine patterns exceeding the critical resolution of an exposure apparatus using ultraviolet (UV) rays, deep ultraviolet (DUV) rays, extreme ultraviolet (EUV) rays, or an electron beam (EB) as a light source.

Thus, for example, pattern formation techniques called narrow space formation techniques have been proposed which form, to desired shapes, patterns finer than the critical resolution of the exposure device using any of the above-described light sources. An example of the narrow space formation techniques will be described in brief.

First, a resist pattern is formed on a resist film using any of the above-described light sources, and a complementary film that interacts with the resist film on the basis of a predetermined process is formed on the resist film. Subsequently, a kind of crosslinking mixing layer is formed between the resist film and the complementary film by, for example, a baking process. A part of the complementary film which has not been mixed is removed from the resist film to form a narrow space portion narrower than a space portion in the resist film constituting the resist pattern. This narrow space formation technique enables formation of via plugs finer than the critical resolution of the exposure apparatus using any of the above-described light sources, and interconnects having a line width smaller than the critical resolution.

As one type of narrow space formation technique, a technique called Resolution Enhancement Lithography Assisted by Chemical Shrink (RELACS™) has been proposed. As disclosed in, for example, a Web feature article “Semiconductor 0.1-m hole pattern formation technique RELACS” presented by Mitsubishi Electric Corporation, this technique first forms, by coating, an upper layer on a space pattern such as a hole which is formed in the resist film as a part of the resist pattern. Subsequently, the resist film and the upper coating film are subjected to a heating process to allow acid components in the resist film to interact with the upper coating film to form a thermosetting layer at the interfacial portion between the films. The upper coating film is then removed except for a part corresponding to the thermosetting layer by rinsing in pure water. A space pattern is thus formed which is finer than that such as a hole which is formed in the resist film.

However, this technique may fail to sufficiently remove the upper coating film except for the part corresponding to the thermosetting layer. Thus, the fine space pattern such as the hole may fail to be formed.

Furthermore, a technique of enabling formation of a thin deposit film on a resist and thus a finer space is described on an Internet home page as Lam Research Corporation (2300 Motif™) and in Proc. of SPIE Vol. 6519 (2007). This technique is effective for further miniaturizing patterns with sizes close to the critical resolution.

However, a pattern having a size close to the critical resolution and which is otherwise open may be in a footing condition or may be half-open owing to a slight fluctuation in the lithography process, for example, a variation in exposure amount or baking temperature, or a variation in rinse conditions during development. In this condition, application of RELACS or 2300MOTIF, described above, may result in inappropriate pattern formation such as an unopened pattern.

### BRIEF SUMMARY OF THE INVENTION

According to an aspect of the invention, there is provided a pattern forming method comprising patterning a resist film provided on one major surface of a process target substrate to form a resist pattern, and forming a moisture-containing film on a front surface of the process target substrate in a space portion of the resist pattern, irradiating the moisture-containing film with light, and supplying a liquid containing moisture to the moisture-containing film.

According to another aspect of the invention, there is provided a pattern forming method comprising patterning a resist film provided on one major surface of a process target substrate to form a resist pattern, carrying out a solubilization process on the resist film remaining in a space portion of the resist pattern, supplying a liquid for removing the resist film to remove the resist film remaining in the space portion of the resist pattern, introducing a material for a pattern forming complementary film which is formed into a film through interaction with the resist film, into the space portion of the resist pattern, allowing the material for the pattern forming complementary film to interact with the resist film to selectively form the pattern forming complementary film on inner side surfaces of the space portion, and removing a part of the material for the pattern forming complementary film which has not been formed into a film, from inside the space portion with the remaining part of the pattern forming complementary film left in the space portion to expose a part of a bottom surface of the space portion.

According to still another aspect of the invention, there is provided a pattern forming method comprising patterning a resist film provided on one major surface of a process target substrate to form a resist pattern, carrying out a solubilization process on the resist film remaining in a space portion of the resist pattern, supplying a liquid for removing the resist film, the liquid containing a material for a pattern forming complementary film which is formed into a film through interaction with the resist film, allowing the material for the pattern forming complementary film to interact with the resist film to selectively form the pattern forming complementary film on inner side surfaces of the space portion, and removing a part of the material for the pattern forming complementary film which has not been formed into a film, from inside the space portion with the remaining part of the pattern forming complementary film left in the space portion to expose a part of a bottom surface of the space portion.

### BRIEF DESCRIPTION OF THE SEVERAL VIEWS OF THE DRAWING

FIG. 1 is a flowchart showing a pattern formation method according to a first embodiment of the present invention;

FIG. 2A is a sectional view illustrating a first step of the pattern formation method according to the first embodiment of the present invention;

FIG. 2B is a sectional view illustrating a second step of the pattern formation method according to the first embodiment of the present invention;

FIG. 3A is a sectional view illustrating a third step of the pattern formation method according to the first embodiment of the present invention;

FIG. 3B is a sectional view illustrating a fourth step of the pattern formation method according to the first embodiment of the present invention;

FIG. 4A is a sectional view illustrating a fifth step of the pattern formation method according to the first embodiment of the present invention;

FIG. 4B is a sectional view illustrating a sixth step of the pattern formation method according to the first embodiment of the present invention;

FIG. 5A is a sectional view illustrating a first step of a method of manufacturing an electronic device according to the first embodiment of the present invention;

FIG. 5B is a sectional view illustrating a second step of the method of manufacturing the electronic device according to the first embodiment of the present invention;

FIG. 5C is a sectional view illustrating a third step of the method of manufacturing the electronic device according to the first embodiment of the present invention;

FIG. 6 is a flowchart showing a pattern formation method according to a second embodiment of the present invention;

FIG. 7A is a sectional view illustrating a first step of the pattern formation method according to the second embodiment of the present invention;

FIG. 7B is a sectional view illustrating a second step of the pattern formation method according to the second embodiment of the present invention;

FIG. 8A is a sectional view illustrating a third step of the pattern formation method according to the second embodiment of the present invention;

FIG. 8B is a sectional view illustrating a fourth step of the pattern formation method according to the second embodiment of the present invention;

FIG. 9A is a sectional view illustrating a fifth step of the pattern formation method according to the second embodiment of the present invention;

FIG. 9B is a sectional view illustrating a sixth step of the pattern formation method according to the second embodiment of the present invention;

FIG. 10 is a flowchart showing a pattern formation method according to a third embodiment of the present invention;

FIG. 11A is a sectional view illustrating a first step of the pattern formation method according to the third embodiment of the present invention;

FIG. 11B is a sectional view illustrating a second step of the pattern formation method according to the third embodiment of the present invention;

FIG. 12 is a flowchart showing a pattern formation method according to a fourth embodiment of the present invention;

FIG. 13 is a sectional view illustrating a step of the pattern formation method according to the fourth embodiment of the present invention;

FIG. 14 is a flowchart illustrating a pattern formation method according to a fifth embodiment of the present invention;

FIG. 15A is a sectional view illustrating a step of the pattern formation method according to the fifth embodiment of the present invention;

FIG. 15B is a sectional view illustrating a step of the pattern formation method according to the fifth embodiment of the present invention;

FIG. 16 is a sectional view illustrating pattern modification in a pattern formation method according to a sixth embodiment of the present invention;

FIG. 17A is a sectional view illustrating the pattern formation method according to the sixth embodiment of the present invention and showing that an opening pattern is normal;

FIG. 17B is a sectional view illustrating the pattern formation method according to the sixth embodiment of the present invention and showing that the opening pattern is normal and that a normal pattern has thus been formed;

FIG. 18A is a sectional view illustrating the pattern formation method according to the sixth embodiment of the present invention and showing that the opening pattern is in a footing condition;

FIG. 18B is a sectional view illustrating the pattern formation method according to the sixth embodiment of the present invention and showing that the opening pattern is in the footing condition and that the pattern is thus unopened;

FIG. 19A is a sectional view illustrating the pattern formation method according to the sixth embodiment of the present invention and showing that the opening pattern is half-open;

FIG. 19B is a sectional view illustrating the pattern formation method according to the sixth embodiment of the present invention and showing that the opening pattern is half-open and that the pattern is thus unopened; and

FIG. 20 is a flowchart illustrating the pattern formation method according to the sixth embodiment of the present invention.

### DETAILED DESCRIPTION OF THE INVENTION

### First Embodiment

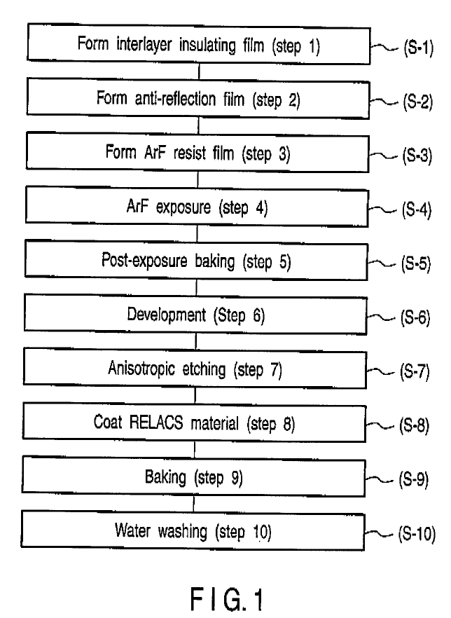

First, a pattern formation method according to a first embodiment of the present invention will be described with reference to FIGS. 1, 2A, 2B, 3A, 3B, 4A, 4B, 5A, 5B, and 5C. In the present embodiment, a technique will be mainly described which forms a narrow space by allowing a pattern forming complementary film to act on a resist pattern. In addition to allowing formation of a narrow space, the narrow space formation technique according to the present embodiment reduces defects in a space portion.

For example, resist defects remaining in a space portion (space pattern) of a first resist pattern formed of a resist film are removed, while the space portion is narrowed. Then, on the basis of the narrowed space pattern, a hole pattern for forming plugs such as via plugs or contact plugs or a trench pattern for forming interconnects is formed. A second resist pattern having a narrow space pattern formed according to the present embodiment is a micropattern with few defects. Thus, application of the present embodiment improves the reliability of various electronic devices such as semiconductor devices and liquid crystal devices. That is, the pattern formation technique according to the present embodiment is applicable to various methods of manufacturing electronic devices, such as methods of manufacturing semiconductor devices and liquid crystal devices. The present embodiment will be specifically described below in detail.

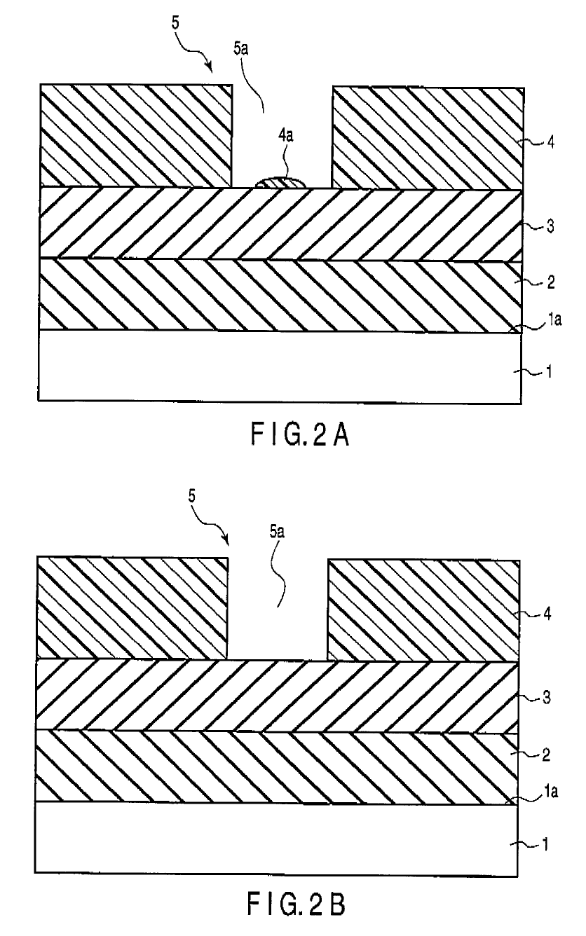

First, as shown in FIGS. 1 and 2A, an interlayer insulating film 2 made up of, for example, SiO₂ is formed, as a kind of process target film, on one major surface (front surface) of a semiconductor substrate 1 as a process target substrate. This is shown as step 1 (S-1) in a flowchart in FIG. 1. Subsequently, also as a kind of process target film, an anti-reflection film 3 for ArF light is formed on the interlayer insulating film 2 by a spin coating method. This is shown as step 2 (S-2) in the flowchart in FIG. 1. Subsequently, a chemical amplification resist film 4 that is photosensitive to ArF light is formed on the anti-reflection film by the spin coating method. This is shown as step 3 (S-3) in the flowchart in FIG. 1.

Subsequently, a latent image is formed on the resist film 4 using radiation or a charged particle line. In this case, while aligned to an interconnect pattern (not shown) to be formed on the semiconductor substrate 1, a pattern 5a described below is exposed using an ArF exposure apparatus (not shown). This is shown as step 4 (S-4) in the flowchart in FIG. 1. In this ArF exposure step, although not shown in the drawings, a mask pattern including a hole pattern formed on an exposure mask installed on the ArF exposure apparatus is projected on the resist film 4 on the semiconductor substrate 1 so as to be reduced. In the ArF exposure step, the exposure mask and the semiconductor substrate 1 are moved relative to each other to expose and transfer the mask pattern to a front surface of the resist mask 4 while aligning the mask pattern.

Subsequently, a heating process is performed, at at least about 75° C., on the whole semiconductor substrate 1 including the resist film 4 to which the mask pattern has been exposed and transferred. This is shown as step 5 (S-5) in the flowchart in FIG. 1. The temperature at which the post-exposure baking process is carried out needs to be set to a value at which acid diffusion reaction occurs effectively in the resist film 4. In this case, the post-exposure baking process is carried out at about 120° C., at which the dimensional uniformity of the developed resist pattern falls within an acceptable range. Then, the whole semiconductor substrate 1 subjected to the post-exposure baking process is cooled down to the room temperature.

Subsequently, an area of the resist film 4 in which the latent image is formed or an area of the resist film in which the latent image is not formed is selectively removed to form a first resist pattern 5. In this case, the cooled resist film 4 is subjected to a developing process to form the first resist pattern 5 including the hole pattern 5a as a space pattern (space portion), on the resist film 4. This is shown as step 6 (S-6) in the flowchart in FIG. 1. In this case, the first hole pattern 5a formed has a diameter of about 100 nm. Furthermore, after completion of the developing process step, the present inventors checked the resulting structure for defects using a deep ultra violet (DUV) light defect inspecting apparatus having a resolution of about 60 nm. Then, no unopened first hole pattern 5a was observed in a front surface of the first resist pattern 5. However, an unwanted resist film 4a remained inside the first hole pattern 5a as a residue.

Then, as shown in FIGS. 1 and 2B, the first resist pattern 5a is subjected to an anisotropic etching process, a kind of dry etching, to remove the residue 4a from inside the first hole pattern 5a. This is shown as step 7 (S-7) in the flow chart shown in FIG. 1. In this case, the semiconductor substrate 1 on which the first resist pattern 5 is formed is installed in a dry etching apparatus. Mainly the first hole pattern 5a is then dry etched by oxygen plasma. At this time, dry etching conditions are set such that an etching rate in a direction perpendicular to the front surface 1a of the semiconductor substrate 1 is higher than those in the other directions. More specifically, the dry etching may be performed at an etching rate at which the residue 4a in the first hole pattern 5a can be scraped away and removed from above depending on the size or amount of the residue 4a. In this case, the dry etching is performed at an etching rate at which the residue 4a of thickness (height) about 5 nm can be scraped away and removed from above. Even for the first hole pattern 5a that appears not to have the residue 4a, this process is effective for removing organic contaminants from the front surface of the space pattern.

The residue removal process is not limited to dry etching. Any other process can be used which corresponds to a method enabling removal of the residue 4a from inside the first hole pattern 5a or a reduction in the size of residue such that possible pattern defects can be avoided. However, in the residue removal process, the increased width of the space pattern degrades a subsequent hole reducing effect. Thus, the residue removal process is preferably performed by anisotropic etching such that the etching rate in the direction orthogonal to the front surface 1a of the semiconductor substrate 1 is higher than those in the other directions.

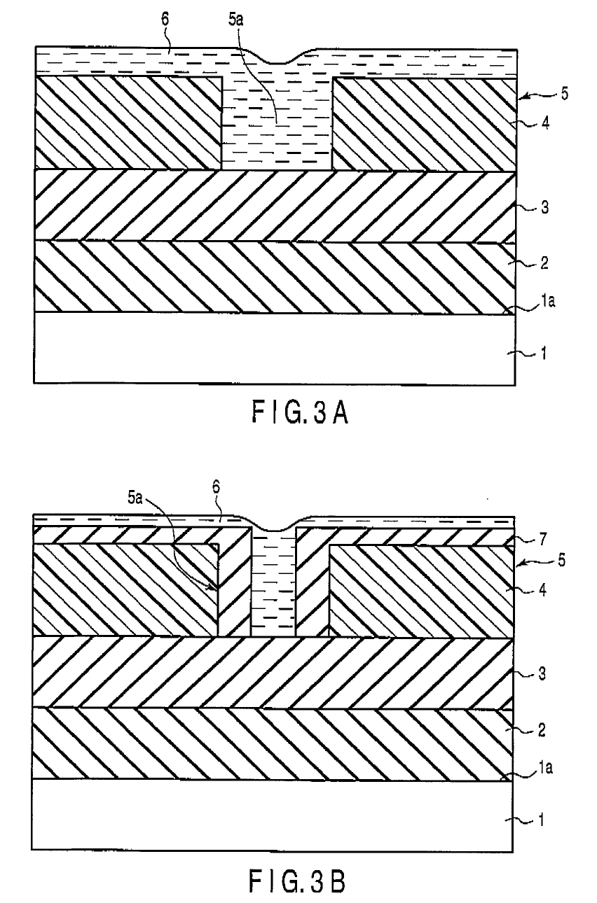

Then, as shown in FIGS. 1 and 3A, a material 6 for a pattern forming complementary film 7 is provided on the first resist pattern 5 (resist film 4) by the spin coating method while being filled into the hole pattern 5a from which the residue 4a has been removed; the material 6 is formed into the pattern forming complementary film 7 by interaction with the resist film 4. This is shown as step a (S-8) in the flowchart in FIG. 1. The material 6 of the pattern forming complementary film 7 is called a RELACS™ (Resolution Enhancement Lithography Assisted by Chemical Shrink) material.

Then, as shown in FIGS. 1 and 3B, the RELACS™ material 6 and the resist film 4 are subjected to the heating process (baking process) to allow the RELACS™ material 6 and the resist film 4 to interact with each other to form the pattern forming complementary film 7 over the front surface of the first resist pattern 5 (resist film 4). This is shown as step 9 (S-9) in the flowchart in FIG. 1. Specifically, the pattern forming complementary film 7 is formed by carrying out a baking process to thermally crosslink a mixing layer into which the RELACS™ and the resist film 4 are mixed. Thus, the pattern forming complementary film 7 is not formed so as to fill the whole interior of the first hole pattern 5a. The pattern forming complementary film 7 is formed by being selectively grown on an edge of a bottom surface of the hole pattern 5a so as to cover inner side surfaces of the first hole pattern 5a. The pattern forming complementary film 7 is hereinafter referred to as the RELACS™ film. Subsequently, the whole semiconductor substrate 1 on which the RELACS™ film 7 is formed is cooled.

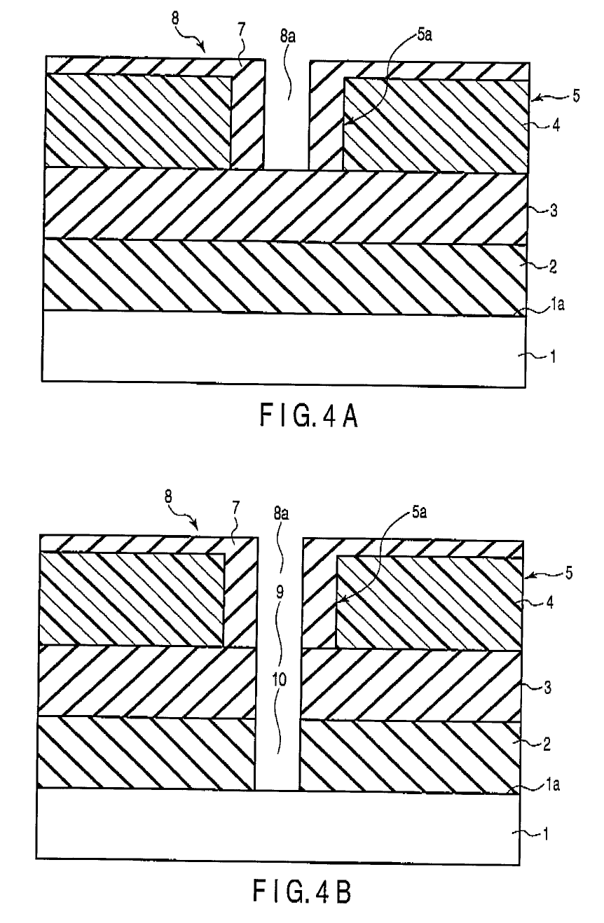

Then, as shown in FIGS. 1 and 4A, the whole cooled semiconductor substrate 1 is washed with, for example, pure water to remove the RELACS™ material 6 that has not been formed into a film yet, from inside the first hole pattern 5a and from the front surface of the first resist pattern 5. Only the RELACS™ film 7 is thus left on the inner side surfaces of the first hole pattern 5a and on the front surface of the first resist pattern 5. This is shown as step 10 (S-10) in the flowchart in FIG. 1. As a result, the first hole pattern 5a is reduced by being partly exposed, that is, exposing the entire area of the first hole pattern 5a expect for the edge of the bottom surface. In this case, the first hole pattern 5a is reduced such that the diameter of the pattern 5a decreases from about 100 nm, described above, to about 80 nm. A narrow space pattern to which the first hole pattern 5a has been reduced is hereinafter referred to as a second hole pattern 8a. A resist pattern including the second hole pattern 8a and composed of the first resist pattern 5 and the RELACS™ film 7 is referred to as a second resist pattern 8. Upon completion of the washing process step, the present inventors inspected the resulting semiconductor substrate for defects using DUV light having a resolution of about 60 nm. Then, the ratio of unopened second hole pattern 8a to open second hole patterns 8a was about 1 to 100 million. The main steps of the pattern formation method according to the present embodiment are thus completed.

Then, as shown in FIGS. 1 and 43, the anti-reflection film 3 is processed through the second resist pattern 8 as a mask to form a first through-hole 9 penetrating the anti-reflection film 3 to communicate with the second hole pattern 8a. In this case, the first through-hole 9 is formed by using oxygen plasma to subject the anti-reflection film 3 to the anisotropic etching process (dry etching process) such that the etching rate in the direction orthogonal to the front surface 1a of the semiconductor substrate 1 is higher than those in the other directions. Subsequently, the interlayer insulating film 2 is processed through the first resist pattern 8 and the anti-reflection film 3 in which the first through-hole 9 is formed, as a mask to form a second through-hole 10 penetrating the interlayer insulating film 2 to communicate with the first through-hole 9. In this case, the second through-hole 10 is formed by subjecting the interlayer insulating film 2 to the dry etching process under the same conditions as those under which the first through-hole 9 is formed, using a fluorocarbon-containing gas. The plug forming hole pattern 10 is fine and has a diameter of about 80 nm, similarly to the second hole pattern 8a.

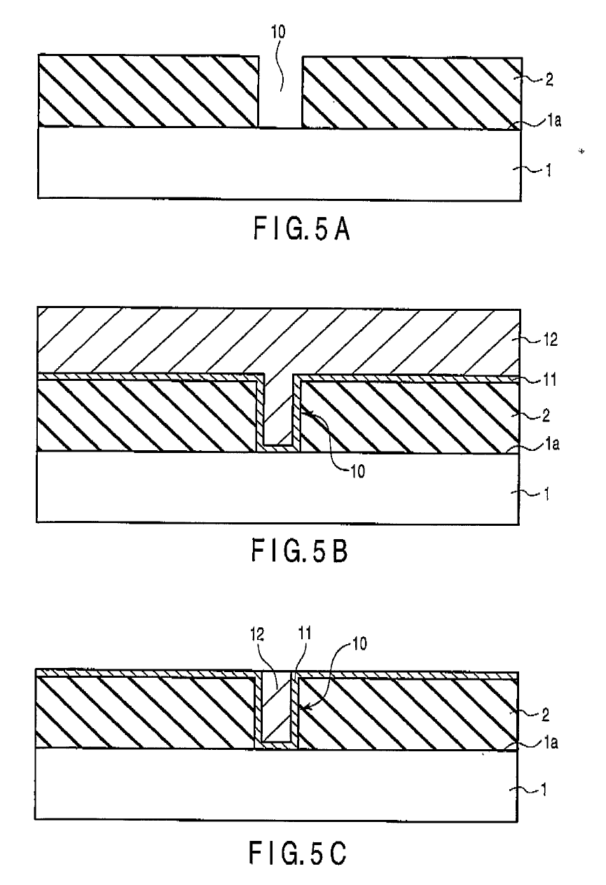

Then, as shown in FIG. 5A, the resist film 4 and the anti-reflection film 3 are removed from a front surface of the interlayer insulating film 2 in which the plug forming hole pattern 10 is formed. Subsequently, as shown in FIG. 5B, a barrier metal film 11 and a conductor 12 constituting a contact plug (via plug) are sequentially stacked inside the second through-hole 10 and on the front surface of the interlayer insulating film 2. Then, as shown in FIG. 5C, the conductor 12 and the barrier metal film 11 is filled into the plug forming hole pattern 10 by, for example, a CMP method. Thus, a fine contact plug 12 of diameter about 80 nm is formed inside the interlayer insulating film 2 so that side surfaces and a bottom surface of the plug 12 are covered with the barrier metal film 11. The main steps of the method of manufacturing the electronic device according to the present embodiment are thus completed.

Now, a comparative example of the present embodiment will be described. The present inventors experimentally formed the RELACS™ film without carrying out the anisotropic etching step (residue removal process step) described above with reference to FIG. 2B and corresponding to step 7 (S-7) in the flowchart in FIG. 1. That is, the RELACS™ film is selectively grown and formed on side wall surfaces and a top surface of the first resist pattern without removing the residue from inside the first hole pattern. Thus, the diameter of the first hole pattern was reduced from about 100 nm to about 80 nm to form the second hole pattern.

The present inventors used the same DUV light defect inspecting apparatus as that used in the present embodiment, which had a resolution of about 60 nm, to inspect, for defects, the entire front surface of the resist film in which the second hole pattern is formed by the above-described steps. Then, the ratio of unopened second hole patterns to open second hole patterns was about 1 to 10 thousand. Furthermore, the sectional shape of the unopened second hole pattern was examined to find a large residue made up of a residue of the resist film and the RELACS™ film deposited on the residue. More specifically, the present inventors found that the residue made up of the resist film and the RELACS™ film was formed on the bottom surface and inner side surfaces of the second hole pattern; the residue was formed as a result of the growth of the resist film and the RELACS™ film through the interaction between the resist film and the RELACS™ material, and had a width of about 70 nm. Such a residue is expected to be formed by an incomplete developing process resulting from the difficulty of substitution of a developer inside the first hole pattern in the stage of the developing process (step 6). It has thus been found that the residue made up of the resist film and the RELACS™ film formed the unopened second hole pattern, which was detected as a defective pattern.

Thus, unlike in the case of the present embodiment, in the comparative example in which the RELACS™ film is formed with the residue removal process step (step 7) following the developing step (step 6) omitted, an unwanted resist film is likely to remain inside the first hole pattern. When the resist film remains inside the first hole pattern, the RELACS™ film is formed on the residue. The residue thus grows further, and the hole is likely to be blocked. That is, the first hole pattern is unlikely to be formed to have the desired opening shape and is thus likely to be defective. The defective pattern is prone to make defective a plug forming pattern or an interconnect forming pattern formed on the basis of the defective pattern. When filled into the defective plug or interconnect forming pattern, a conductor has difficulty ensuring a sufficient contact. As a result, the performance, quality, reliability, durability, and the like of the electronic device are degraded.

The present inventors experimentally formed a plug forming pattern on the basis of the first and second hole patterns formed by the pattern formation method according to the above-described comparative example. The results of the experiments show that the ratio of unopened plug forming patterns to acceptable plug forming patterns was about 1 to 3,000. That is, the results show that the occurrence rate of defective patterns in formation of the plug forming pattern was at least three times as high as that of defective patterns in formation of the second hole pattern. Such defective openings have been found to result from many defects caused by the above-described residue when the first hole pattern shrinks to the second hole pattern. Furthermore, a plug forming pattern with such a defective opening is formed by a complete failure to etch the SiO₂ film constituting the interlayer insulating film or stoppage of the etching of the SiO₂ film during the process. Moreover, after the etching of the SiO₂ film, the results of the inspection after the hole shrinkage showed the increase in the defective pattern occurrence rate. This is because many plug forming patterns with grown residues as well as the RELACS™ film remained on the residue of the resist film, the size of which was equal to or less than a detection sensitivity.

In contrast, in the present embodiment, the probability of the occurrence of the unopened plug forming pattern 10 after the formation of the plug forming pattern 10 corresponds to the ratio of about 1 to 100 million as described above. That is, in the present embodiment, the residue removal process step (step 7) is carried out after the developing step (step 6) to remove the residue 4a of the resist film 4 from inside the first hole pattern 5a, and the RELACS™ film 7 is formed for hole shrinkage. Thus, the defective pattern occurrence rate did not increase after the step of etching the SiO₂ film. Accordingly, the present embodiment significantly improves the probability of the occurrence of the unopened plug forming pattern 10 after the formation of the plug forming pattern 10 compared to the above-described comparative example.

As described above, even for the fine narrow space pattern 8a exceeding the limit of the resolution of the exposure apparatus, the first embodiment enables many such narrow space patterns 8a to be formed to the desired shape while reducing the defect occurrence rate of the narrow space pattern 8a. Furthermore, by forming the contact plug 12 and the like on the basis of the narrow space pattern 8a, various electronic devices such as semiconductor devices and liquid crystal devices can be manufactured so as to be highly miniaturized and integrated, with degradation of the performance, quality, reliability, durability, and the like of the device inhibited. Additionally, when fine contact or via plugs are normally formed, a technique called double via may be used which forms two contact or via plugs for each interconnect as a relief measure against a defect such as inappropriate electric conductance. However, this technique needs to form the two plugs and is thus likely to increase the number of steps required, reducing production efficiency. In contrast, the present embodiment enables fine contact or via plugs to be formed with almost no defect involved. Consequently, forming one contact or via plug for each interconnect is sufficient. Thus, the present embodiment enables improvement of the production efficiency of the electronic device and a reduction in manufacturing costs.

In the present embodiment, the ArF exposure is applied to the method as described above. However, the present invention is not limited to this aspect. For example, effects similar to those described above can be exerted by using KrF light as an exposure light source instead of the ArF light and applying the present embodiment to an exposure process using a KrF chemical amplification resist instead of the ArF chemical amplification resist 4. Alternatively, effects similar to those described above can be exerted by applying the present embodiment to an EUV exposure process allowing finer hole patterns to be exposed or an exposure process using an I line from a mercury lamp to expose relatively large patterns in contrast to the EUV exposure process. Moreover, of course, effects similar to those described above can be exerted by applying the present embodiment to a case in which many holes are unopened, for example, in what is called a nano-imprint lithography process, which requires a very high processing accuracy, the tips of pillar patterns are broken or worn.

The present embodiment carries out the process of reducing the diameter of the first hole pattern 5a from about 100 nm to about 80 nm. However, the size of the first hole pattern 5a or the second hole pattern 8a is not limited to this aspect. The present embodiment is of course applicable to, for example, a step of reducing the width of a hole pattern or a space pattern with a size close to a critical resolution determined by illumination conditions for the exposure apparatus and NA conditions. Furthermore, the amount of shrinkage from the first hole pattern 5a to the second hole pattern 8a (the amount by which the hole is narrowed) is about 20 nm. However, the shrinkage amount is not limited to this aspect. In general, the defective pattern occurrence rate increases consistently with the shrinkage amount. Thus, of course, an increase in shrinkage amount during the narrow space pattern forming process makes the applicability of the present embodiment more advantageous.

Moreover, the normal anti-reflection film 3 may contain acid. The acid may interact with the RELACS™ material 6 to form the RELACS™ film 7 all over the bottom surface of the first hole pattern 5a. Thus, in the present embodiment, the temperature at which the anti-reflection film 3 is formed is increased to one at which the acid in the anti-reflection film is deactivated. This inhibits the RELACS™ film 7 from being formed on the anti-reflection film 3, forming the bottom surface of the first hole pattern 5a.

In contrast, if the temperature at which the anti-reflection film 3 is formed is lower than that at which the acid in the anti-reflection film is deactivated, the acid continues to be present in the anti-reflection film 3. Thus, when the anti-reflection film 3 is formed at a low temperature, the RELACS™ film 7 may be formed on a part of the anti-reflection film 3 exposed from the bottom surface of the first hole pattern 5a, though this part of the RELACS™ film 7 is not so thick as the part of the RELACS™ film 7 formed on the front surface of the resist pattern 5 (resist film 4). However, since the part of the RELACS™ film 7 formed on the anti-reflection film 3 is very thin, this part is scraped away when the first through-hole 9 is formed in the anti-reflection film 3. Therefore, in this case, effects similar to those described above can be exerted.

### Second Embodiment

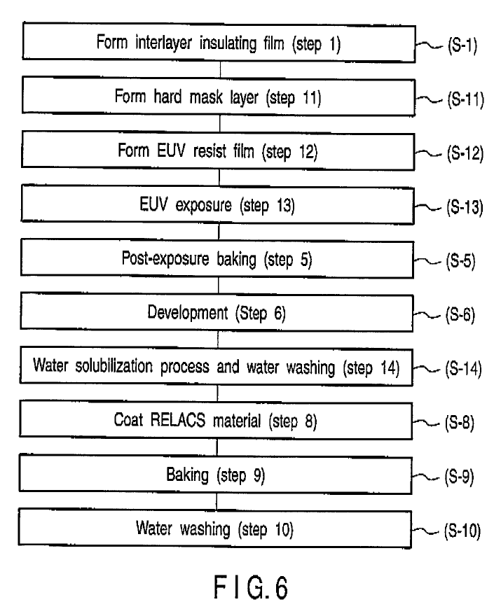

Now, a pattern forming method according to a second embodiment of the present invention will be described with reference to FIGS. 6, 7A, 7B, 8A, 8B, 9A, and 9B. The same components of the second embodiment as those of the first embodiment are denoted by the same reference numerals and will not be described in detail. Unlike the first embodiment, the present embodiment uses a hard mask layer instead of the anti-reflection film. Furthermore, in exposing the resist pattern, soft X-rays (extremely short wavelength ultraviolet rays; extreme ultraviolet [EUV]) are used as an exposure light source instead of the ArF light. Moreover, instead of the anisotropic etching, a liquid is used to remove the residue from inside the hole pattern. The pattern forming method according to the present embodiment will be specifically described in detail.

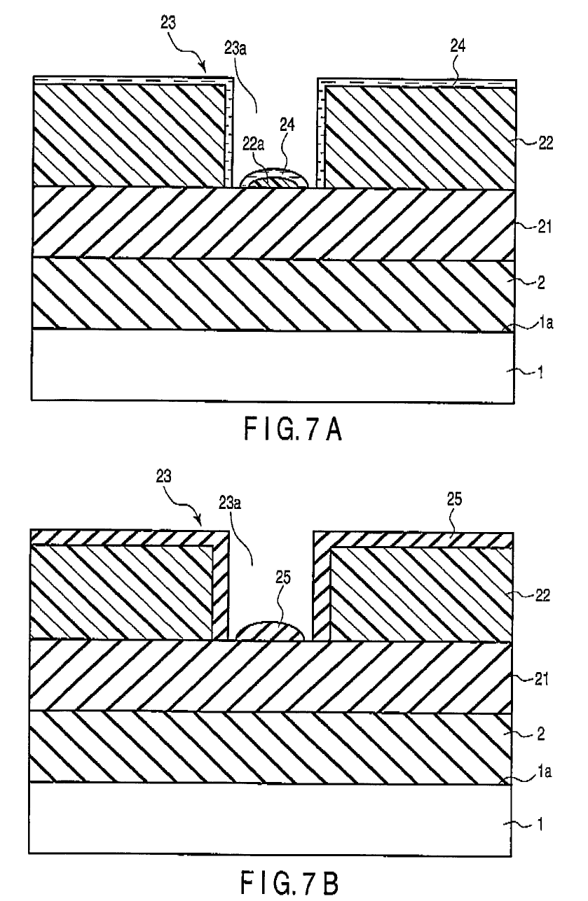

First, as shown in FIGS. 6 and 7A, a hard mask layer 21, a kind of process target film, is formed by the spin coating method on the interlayer insulating film 2 formed on the front surface 1a of the semiconductor substrate 1. In this case, the hard mask layer 21 was produced by sequentially forming a carbon-containing coating film and a spin on glass coating film. This is shown as step 11 (S-11) in a flowchart in FIG. 6. Subsequently, a chemical amplification resist film 22 that is sensitive to soft X-rays (EUV) is formed on the hard mask layer 21 by the spin coating method. This is shown as step 12 (S-12) in a flowchart in FIG. 6.

Subsequently, as is the case with step 4 (S-4) according to the first embodiment, a latent image (not shown) is selectively formed on the resist film 22. However, unlike in the case of the first embodiment, in the present embodiment, the resist film 22 is exposed to the latent image using an EUV exposure apparatus (not shown) instead of the ArF exposure apparatus. This is shown as step in (S-13) in a flowchart in FIG. 6.

Then, as is the case with step 5 (S-5) according to the first embodiment, the whole semiconductor substrate 1 including the resist film 22 on which the latent image is formed is heated at about 75° C. The whole semiconductor substrate 1 subjected to the post-exposure baking process is cooled down to the room temperature.

Subsequently, as is the case with step 6 (S-6) according to the first embodiment, a first resist pattern 23 including a first hole pattern 23a is formed on the resist film 22. However, the present embodiment forms the first hole pattern 23a of diameter about 45 nm instead of the first hole pattern 5a of diameter about 100 nm as in the case of the first embodiment. An unwanted resist film 22a remained inside the first hole pattern 23a as in the case of the first hole pattern 5a according to the first embodiment.

Then, as is the case with step 7 (S-7) according to the first embodiment, the residue 22a is removed from inside the first hole pattern 23a. However, unlike the first embodiment, the present embodiment does not use the anisotropic etching to remove the residue 22a. In the present embodiment, first, a solubilization process is carried out on the resist pattern 23 so as to make the resist film 22 easily soluble in a liquid used to remove the residue 22a remaining inside the first hole pattern 23a. Subsequently, a removing liquid is used to remove the residue 22a. This process will be more specifically described below.

First, a water solubilization process is carried out on the entire front layer portion of the first resist pattern 23 and the entire residue 22a so that the front surface of the resist film 22 is easily soluble in an aqueous solution. In this case, the front surface of the resist film 22 (first resist pattern 23) is washed in water. The resist film 22 is then spin dried with drying time appropriately adjusted. This allows the front surface of the resist film 22 to adsorb moisture (water vapor) to form a thin moisture-containing film 24. This adsorbing process is not limited to the above-described method. Although not shown in the drawings, the thin moisture film 24 can also be formed on the front surface of the resist film as follows. With a water film formed on the front surface of the resist film 22, the semiconductor substrate 1 is cooled down to at most about 0° C. to form a layer of ice on the front surface of the resist film 22. The film of unfrozen water is quickly removed from the front surface of the resist film 22 to form a film of ice of thickness about 1 μm on the front surface of the resist film 22. Alternatively, the thin moisture film 24 can be formed on the front surface of the resist film 22 by cooling the semiconductor substrate 1 or causing moisture condensation on the semiconductor substrate 1, in a high humidity area.

Then, as shown in FIGS. 6 and 7B, to absorb moisture from the moisture-containing film 24 to produce radicals, the resist film 22 (the first resist pattern 23) having the moisture-containing film 24 formed on the front surface is irradiated with light with a wavelength λ of less than about 200 nm. Thus, moisture adsorbed on the first resist pattern 23 is radicalized to add hydroxyl groups (OH groups) 25 to a front surface of the first resist pattern 23, which is a hydrophobic resin layer. As a result, the front layer portion of the first resist pattern 23 is altered to a hydrophilicized layer 25. Although not shown in the drawings, an example of a simple apparatus capable of irradiating the resist film 22 with light with a wavelength λ of less than about 200 nm is an excimer lamp. Preferably, an exposure light source for the excimer lamp is, for example, an Xe₂ light source with a wavelength λ of 172 nm, an Kr₂ light source with a wavelength λ of 146 nm, or an Ar₂ light source with a wavelength λ of 126 nm. The results of the present inventors' experiments show that the reduced wavelength of the irradiation light emitted to the resist film 22 allows the advancement of the irradiation light to be held back at the film surface. This allows easy inhibition of dishing of the resist pattern 23 during a water washing step described below.

Of course, the water solubilization process described above and made up of the adsorption process and the light irradiation process is similarly carried out on the residue 22a in the first hole pattern 23a. Thus, the residue 22a is subjected to reaction similar to that described above and thus altered to the hydrophilicized residue 25.

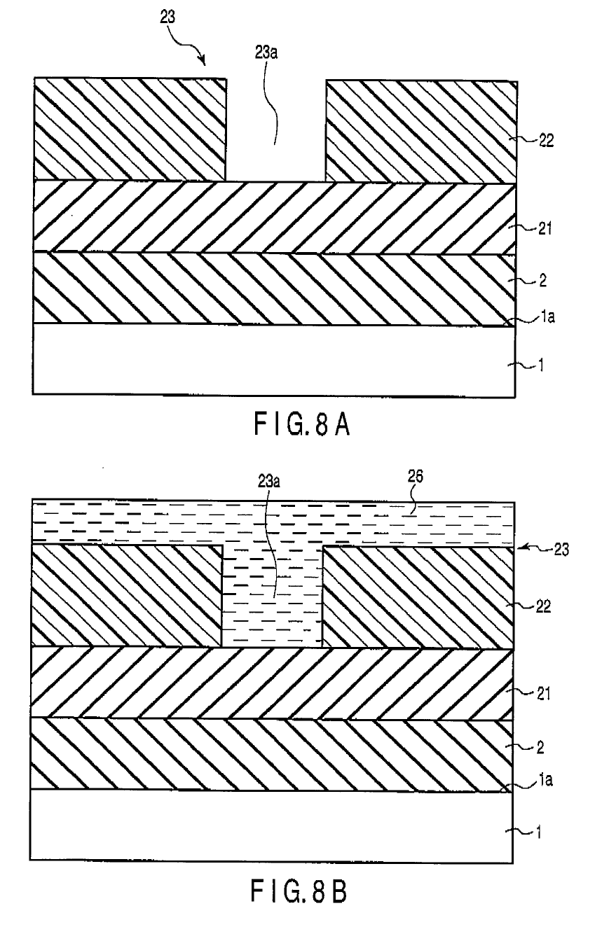

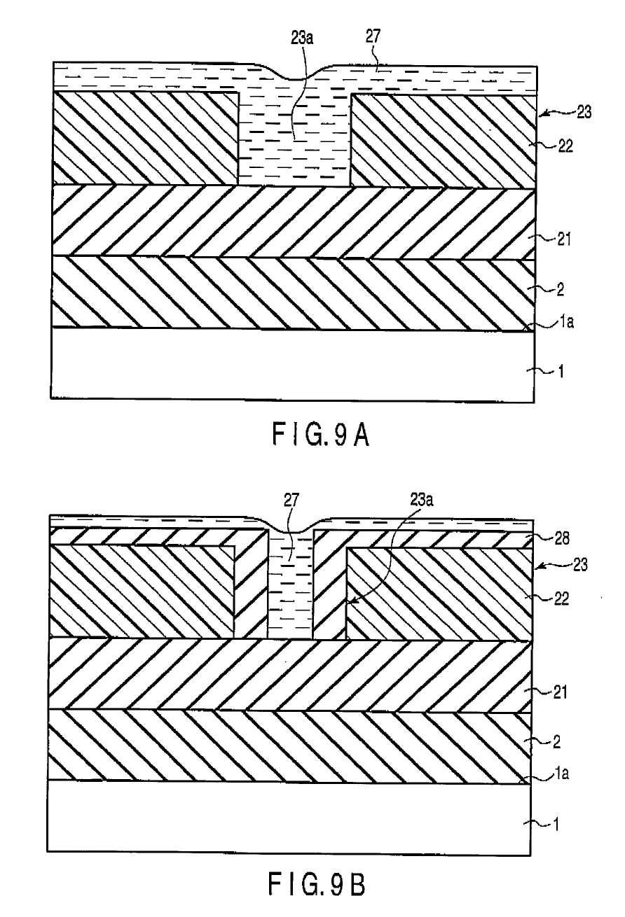

Then, as shown in FIGS. 6 and 8A, washing is performed on the front surface of the first resist pattern 23 having the hydrophilicized layer 25 formed on the front layer portion and the hydrophilicized residue 25. Thus, the front layer portion of the first resist pattern 23 (resist film 22) is dissolved by about 3 nm. The hydrophilicized residue (resist defect) 25 of width about 30 nm remaining in the first hole pattern 23a is removed by being dissolved into water. The water solubilization process and water washing process described above are shown as step 14 (S-14) in the flowchart in FIG. 6. The water solubilization process and water washing process shown in step 14 can be considered to be kinds of a preprocess for a wet etching process and the wet etching process.

Then, as shown in FIGS. 6 and 8B, as is the case with step 8 (S-8) according to the first embodiment, an aqueous solution 26 containing the RELACS™ film 7 is provided on the first resist pattern 23 (resist film 22) so that the aqueous solution 26 fills the interior of the first hole pattern 23a from which the residue 25 has been removed.

Then, as shown in FIGS. 6 and 9A, the water-soluble RELACS™ material 26 is spin and dried. Thus, almost all the moisture contained in the water-soluble RELACS™ material 26 is evaporated to alter the RELACS™ material 26 to a drier spin coated film 27.

Then, as shown in FIGS. 6 and 9B, as is the case with step 9 (S-9) according to the first embodiment, the baking process is carried out on the spin coated film 27 containing the RELACS™ material 26 and the resist film 22. The RELACS™ material in the spin coated film 27 thus interacts with the resist film 22 to form a RELACS™ film 28 over the front surface of the first resist pattern 23 (resist film 22). Then, the whole semiconductor substrate 1 on which the RELACS™ film 28 is formed is cooled.

Then, although not shown in the drawings, the whole cooled semiconductor substrate 1 is washed in water to remove the water-soluble spin coated film 27 that has not been altered to the RELACS™ film 28, from inside the first hole pattern 23a and from the front surface of the first resist pattern 23 as is the case with step 10 (S-10) according to the first embodiment. Thus, only the RELACS™ film 28 is left on inner side surfaces of the first hole pattern 23a and on the front surface of the first resist pattern 23. As a result, the first hole pattern 23a is reduced by being partly exposed, that is, exposing the entire area of the first hole pattern 23a expect for an edge of a bottom surface. In this case, the first hole pattern 23a is reduced such that the diameter of the pattern 23a decreases from about 45 nm, described above, to about 30 nm. A narrow space pattern to which the first hole pattern 23a has been reduced constitutes a second hole pattern. A resist pattern including the second hole pattern and composed of the first resist pattern 23 and the RELACS™ film 28 constitutes a second resist pattern. If in step 10, that is, the water washing step, an aqueous solution is used as a wash fluid instead of water, the aqueous solution can be used for washing. Thus, the main steps of the pattern forming method according to the present embodiment have been completed.

Then, although not shown in the drawings, steps similar to those described in the first embodiment with reference to FIGS. 4B and 5A to 5C are carried out to form, inside the interlayer insulating film 2, a fine contact plug 12 covered with a barrier metal film on side surfaces and a bottom surface and having a diameter of about 45 nm. Thus, the main steps of the method of manufacturing the electronic device according to the present embodiment have been completed.

The present inventors examined the contact hole pattern through which the contact plug was formed in the interlayer insulating film 2 on the basis of the second hole pattern, for a defective hole occurrence rate using a voltage contrast method that utilizes a charge up phenomenon based on irradiation with an electron beam. As a result, the ratio of unopened contact hole patterns to acceptable contact hole patterns was about 1 to 100 million. That is, the examination results show that according to the present embodiment, the occurrence rate of a defect in the contact hole pattern through which the fine contact plug is formed is very low as is the case with the first embodiment. The present embodiment thus drastically improves the defect occurrence rate compared to the case in which the residue removal process is not carried out.

Now, a comparative example of the present embodiment will be described. The present inventors experimentally formed the RELACS™ film with the residue removal process step omitted; the residue removal process step is made up of the water solubilization step and the water washing step and corresponds to step 14 (S-14) in the flowchart in FIG. 6 and described above with reference to FIGS. 7A, 7B, and 3A. That is, as is the case with the comparative example of the first embodiment, described above, the RELACS™ film was selectively grown and formed on the side wall surfaces and top surface of the first resist pattern without removing the residue of the resist film remaining in the first hole pattern. Thus, the diameter of the first hole pattern was reduced from about 45 nm to about 30 nm to form the second hole pattern.

Subsequently, on the basis of the second hole pattern formed by the above-described steps, the contact hole pattern through which the contact plug was formed was formed in the interlayer insulating film. The contact hole pattern was then examined for the defective hole occurrence rate using the voltage contrast method as described above. As a result, the ratio of unopened contact hole patterns to acceptable contact hole patterns was about 10 to 10 thousand. This defective hole occurrence rate of the contact hole pattern is far higher than that according to the present embodiment, described above, that is, about 100 thousand times as high as that according to the present embodiment.

Furthermore, the present inventors examined the sectional shape of the unopened second hole pattern to find that a residue of the resist film of width about 30 nm was formed inside the unopened second hole pattern. The residue of the resist film interacted with the RELACS™ material to grow the residue, thus substantially completely filling the bottom of the second hole pattern. As a result, the ratio of defective hole patterns to acceptable hole patterns was about 10 to 10 thousand. The mechanism of occurrence of such defects is as described in the first embodiment and will thus not be described below.

As described above, the second embodiment can exert effects similar to those of the first embodiment, described above. Unlike the first embodiment, which carries out the residue removal process by the dry etching step, the present embodiment carries out the residue removal process by the wet etching step. In general, the wet etching step offers a higher etching efficiency than the dry etching step, allowing the configuration of an etching apparatus to be simplified. Therefore, the present embodiment is more efficient and requires lower manufacturing costs, than the first embodiment.

The present embodiment utilizes the EUV exposure as described above. However, the present invention is not limited to this aspect. The results of the present inventors' experiments show that effects similar to those described above can also be exerted by applying the present embodiment to the exposure process using the KrF light as an exposure light source instead of the EUV light and using the KrF chemical amplification resist instead of the EUV chemical amplification resist 22 as is the case with the first embodiment. Similarly, the present embodiment has also been found to exert effects similar to those described above when applied to an ArF exposure process or an exposure process using I lines from a mercury lamp.

The present embodiment carries out the process of reducing the diameter of the first hole pattern 23a from about 45 nm to about 30 nm. However, the size of the first hole pattern 23a or the second hole pattern is not limited to this aspect. Like the first embodiment, the present embodiment is of course applicable to, for example, the step of reducing the width of the hole or space pattern with the size close to the critical resolution determined by the illumination conditions for the exposure apparatus and the NA conditions. Furthermore, the amount of shrinkage from the first hole pattern 23a to the second hole pattern (the amount by which the hole is narrowed) is about 15 nm. However, the shrinkage amount is not limited to this aspect. As is the case with the first embodiment, an increase in shrinkage amount during the narrow space pattern forming process makes the applicability of the present embodiment more advantageous.

Furthermore, even if the first pattern 23a such as a space portion or a hole portion need not be shrunk, the present process is of course effectively applicable when the first space pattern 23a exhibits a high defect occurrence rate the after the formation of the resist pattern. Additionally, as is the case with the first embodiment, the application of the present embodiment is not limited to the step of forming a fine space pattern with a size close to the limit of the resolution of the exposure apparatus. The present embodiment is applicable to, for example, a case where in the water solubilization process and water washing process shown in step 14 in FIG. 6, described above, the first resist pattern 23 (resist film 22) dissolves in water or an aqueous solution to expand the first space pattern 23a; the present embodiment then corrects the expanded first space pattern 23a. The present embodiment can form an amount of RELACS™ film 28 corresponding to the expansion of the first space pattern 23a to narrow the first space pattern 23a. Thus, even if a space pattern of a common size is to be formed using normal ultraviolet light as exposure light, the present embodiment can form the pattern to the desired shape while sharply reducing the defect occurrence rate.

Moreover, as described above, in the present embodiment, the step of making the first resist pattern 23 easily soluble corresponds to the step of making the first resist pattern 23 soluble in water. The present embodiment is characterized in that water or an aqueous solution is used as an etchant for removing the residue 22a from inside the first hole pattern 23a. To allow the hydrophobic residue 22a to be removed using water or the aqueous solution, the present embodiment forms the moisture-containing film 24 on the front surfaces of the hydrophobic first resist pattern 23 and residue 22a and then irradiates the first resist pattern 23 with ultra violet light. Thus, hydroxyl group radicals (OH radicals) are produced on the front surfaces of the first resist pattern 23 and residue 22a to allow the front surfaces of the first resist pattern 23 and residue 22a to react with the hydroxyl group radicals. This increases the number of hydroxyl groups in the front layer portions of the first resist pattern 23 and residue 22a having reacted with the hydroxyl group radicals. The hydrophobic first resist pattern 23 and residue 22a thus exhibit a high solubility in water or the aqueous solution.

However, such a principle is not limited to the method of allowing the front surface of the first resist pattern 23 to adsorb water to form the moisture-containing film 24. Similar effects can be exerted by allowing the front surfaces of the first resist pattern 23 and residue 22a to adsorb, for example, hydrogen peroxide instead of water. If the front surfaces of the first resist pattern 23 and residue 22a are allowed to adsorb hydrogen peroxide, the front surfaces of the first resist pattern 23 and residue 22a may be irradiated with light having a wavelength of at most about 250 nm and containing a wavelength that can be absorbed by hydrogen peroxide. Thus, a pattern forming process can be implemented which is similar to that according to the present embodiment, described above. That is, the light emitted to the first resist pattern 23 and residue 22a is not limited to the excimer rays, described above. A pattern forming process similar to that according to the present embodiment, described above, can be implemented by using light containing a wavelength that can be absorbed by water or hydrogen peroxide adsorbed on the front surfaces of the first resist pattern 23 and residue 22a.

Furthermore, in order to remove the unwanted resist film (residue) 22a remaining in the first hole pattern (space portion) 23a after the formation of the resist pattern 23, the above-described method carries out the solubilization process on the resist pattern 23 to make the resist film easily soluble in a liquid and then uses the liquid to carry out the removal process. However, the applied example of this method is not limited to the process of reducing the space pattern after the removal process as in the case of the present embodiment. The method used in the present embodiment is of course applicable to the process of removing the unwanted resist film remaining in the space portion which process proceeds directly to a processing step. In this case, the space pattern not subjected to the solubilization process yet is preferably pre-thinned (pre-slimmed) by the space width over which the resist pattern is expanded as a result of the solubilization process and the removal process.

### Third Embodiment

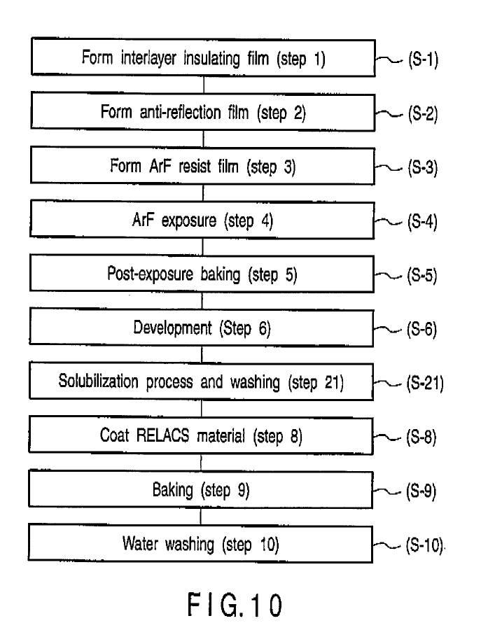

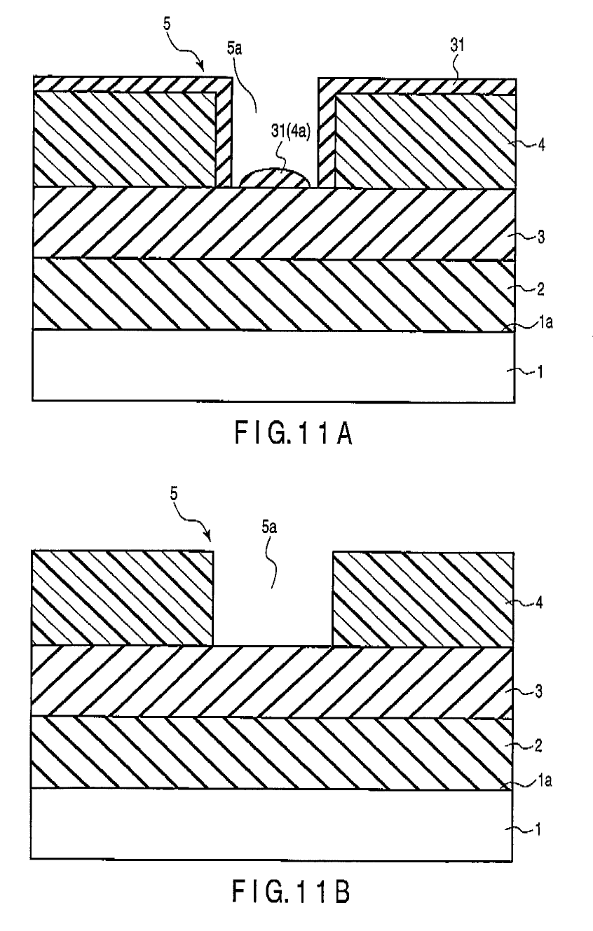

Now, a pattern forming method according to a third embodiment of the present invention will be described with reference to FIGS. 10, 11A, and 11B. The same components of the third embodiment as those of the first and second embodiments are denoted by the same reference numerals and will not be described in detail. The present embodiment is substantially similar to the first embodiment except for the step of removing the residue from inside the hole pattern. The third embodiment will be specifically described below.

First, as shown in FIGS. 10 and 11A, the first resist pattern 5 including the first hole pattern 5a with a diameter of about 100 nm is formed on the resist film 4 provided on the front surface 1a of the semiconductor substrate 1 as is the case with steps 1 (S-1) to 6 (S-6) according to the first embodiment. The unwanted resist film 4a remained inside the first hole pattern 5a as a residue.

Subsequently, as in the case of step 7 (S-7) in the first embodiment, the unwanted resist film 4a is removed from inside the first hole pattern 5a. However, unlike the first embodiment, the present embodiment does not use the anisotropic etching to remove the residue 22a. In the present embodiment, first, the solubilization process is carried out on the resist pattern 5 to make the resist film 4 easily soluble in the liquid for removing the unwanted resist film 4a remaining in the first hole pattern 5a as is the case with step 14 (S-14) according to the second embodiment. Subsequently, the removing liquid is used to carry out the process of removing the unwanted resist film 4a. However, unlike the second embodiment, the present embodiment uses an alkaline solution instead of water to carry out the process of removing the unwanted resist film 4a. The present embodiment will be more specifically described below.

First, the solubilization process is carried out on the entire first resist pattern 5 and the residue 4a of the resist film 4 to make the front surface of the resist film 4 easily soluble in the alkaline solution. Although not shown in the drawings, the front surfaces of the first resist pattern 5 and the resist film 4, forming the residue 4a, are entirely irradiated with ArF light of wavelength 193 nm. Thus, as shown in FIG. 11A, acid is produced on the entire residue 4a made up of the resist film 4 and on the front layer portion of the first resist pattern 5 to alter the entire residue 4a and the front layer portion of the first layer portion of the first resist pattern 5 to an easily soluble film 31 that is easily soluble in an alkaline solution. In this case, the irradiation quantity of ArF light is set so as to meet a condition that when the residue 4a is removed using an alkaline solution with a pH value of about 12 as an etchant, the front layer portion of the resist film 4 is dissolved by about 5 nm to cause dishing.

Then, as shown in FIGS. 10 and 11B, the interior of the first hole pattern 5a is washed using, as a wash fluid, an alkaline solution produced by diluting a tetramethyl ammonium hydroxide (TMAH) developer with pure water and having a pH value of about 12. The residue 31 (4a) remaining in the first hole pattern 5a as a resist defect has already been exposed during patterning. The residue 31 (4a) is thus more soluble in the alkaline solution of pH value about 12 than the resist pattern portion (resist film 4) not exposed during patterning. Consequently, even when having a size of about 20 nm, the residue 31 (4a) can be substantially completely removed from inside the first hole pattern 5a. However, the front layer portion of the resist film 4 is dissolved in the alkaline solution by about 5 nm to cause dishing. The above-described solubilization process (light irradiation process) and washing process are shown as step 21 (S-21) in a flowchart in FIG. 10.

Subsequently, although not shown in the drawings, the RELACS™ film 7 is selectively formed on the edge of the bottom surface of the first hole pattern 5a and over the inner side surfaces of the first hole pattern 5a as is the case with steps 8 (S-8) to 10 (S-10) according to the first embodiment. The second hole pattern 8a of diameter about 80 nm is thus formed. After the completion of the step of forming the second hole pattern 8a, the present inventors performed defect inspections using the DUV light defect inspecting apparatus having a resolution of about 60 nm as is the case with the first embodiment. Then, the ratio of unopened second hole patterns 8a to acceptable second hole patterns 8a was about 1 to 100 million as in the case of the first embodiment. The main steps of the pattern forming method according to the present embodiment are thus completed.

Then, although not shown in the drawings, steps similar to those described in the first embodiment with reference to FIGS. 4B and 5A to 5C are carried out to form, inside the interlayer insulating film 2, the fine contact plug 12 covered with the barrier metal film on the side surfaces and bottom surface and having a diameter of about 80 nm. The main steps of the electronic device manufacturing method according to the present embodiment are thus completed.

As described above, the third embodiment can exert effects similar to those of the first and second embodiments, described above. Furthermore, if the material 6 of the RELACS™ film 7 is an alkaline aqueous solution with a pH value of about 12, the step of removing the residue 4a can be combined with the step of forming the RELACS™ film 7. This will be described below in a fifth embodiment. The pH value of the wash fluid (etchant) need not necessarily be set to about 12. The pH value of the wash liquid may be appropriately changed so as to allow the residue 4a to be appropriately removed depending on the size of the residue 4a or the like.

The present embodiment carries out the process of reducing the diameter of the first hole pattern 5a from about 100 nm to about 80 nm. However, the size of the first hole pattern 5a or the second hole pattern 8a are not limited to this aspect. Like the first embodiment, the present embodiment is of course applicable to, for example, the step of reducing the width of the hole or space pattern with the size close to the critical resolution determined by the illumination conditions for the exposure apparatus and the NA conditions. Furthermore, in the present embodiment, the amount of shrinkage from the first hole pattern 5a to the second hole pattern 8a is about 20 nm (after the alkali washing step, about 30 nm) as is the case with the first embodiment. However, the shrinkage amount is not limited to this aspect. As is the case with the first embodiment, an increase in shrinkage amount during the narrow space pattern forming process makes the applicability of the present embodiment more advantageous.

As described above, in the present embodiment, the step of making the front layer portion of the first resist pattern 5 easily soluble corresponds to the step of producing acid on the front layer portion of the first resist pattern 5 to make the front layer portion easily soluble in the alkaline solution. The present embodiment is characterized in that the alkaline solution is used as a wash liquid (etchant) for removing the residue 4a in the first hole pattern 5a. Furthermore, to produce acid on the front layer portion of the first resist pattern 5, the present embodiment irradiates the front surface of the resist film 4 with light containing a wavelength to which the resist film 4 is sensitive. The intensity of light emitted to the front surface is sufficient when the residue 4a (resist defect) remaining in the first hole pattern 5a can be dissolved by the light and is preferably set such that the degradation of the first resist pattern 5 such as dishing falls within an allowable range.

Moreover, the alkaline wash fluid is not limited to the diluted solution of the TMAH developer described above. Effects similar to those of the present embodiment can be exerted by using an organic alkaline solution such as choline or an inorganic alkaline solution such as KOH as a wash fluid instead of the diluted solution of the TMAH developer. That is, any of various types of alkaline solutions can be used as a wash fluid provided that the concentration and pH value of the solution are set so as to dissolve the residue 4a of the resist film 4 while substantially avoiding dissolving the resist film 4 forming the first resist pattern 5.

### Fourth Embodiment

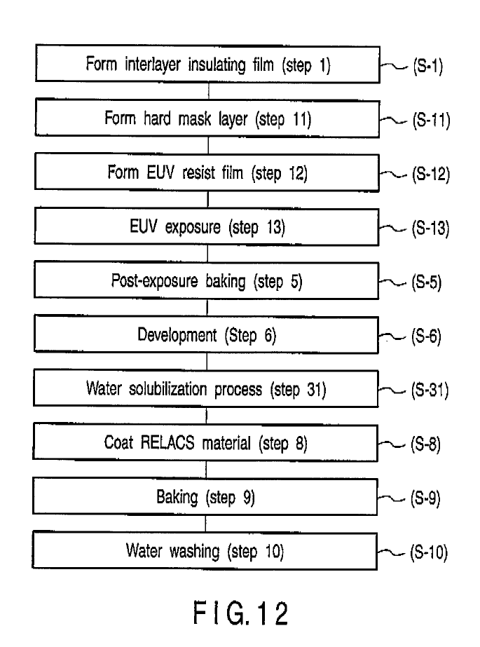

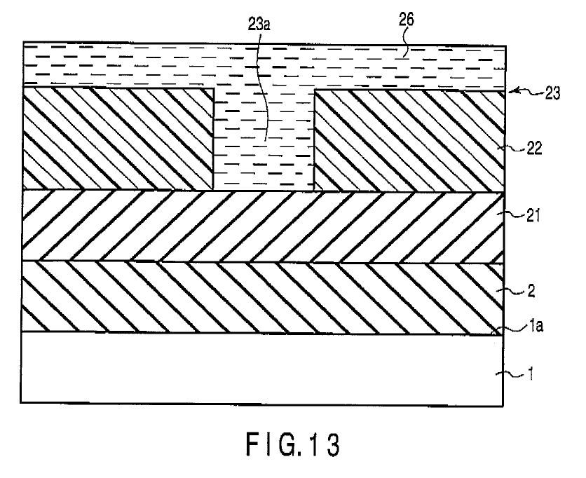

Now, a pattern forming method according to a fourth embodiment of the present invention will be described with reference to FIGS. 12 and 13. The same components of the fourth embodiment as those of the first to third embodiments are denoted by the same reference numerals and will not be described in detail. The present embodiment is substantially similar to the second embodiment except that an aqueous solution containing the RELACS™ material is used as a wash fluid (etchant) for removing the residue. The fourth embodiment will be specifically described below.

First, as shown in FIGS. 12 and 13, the first resist pattern 23 including the first hole pattern 23a with a diameter of about 45 nm is formed on the resist film 22 provided on the front surface 1a of the semiconductor substrate 1 as is the case with steps 1 (S-1) to 6 (S-6) according to the first embodiment. Although not shown in the drawings, the unwanted resist film 22a remained inside the first hole pattern 23a as a residue.

Subsequently, although not shown in the drawings, the solubilization process (water solubilization process) is carried out on the front layer portion of the first resist pattern 23 and the entire residue 22 to make the front surface of the resist film 22 easily soluble in an aqueous solution containing the RELACS™ film 7. In this case, the front surface of the resist film 22 is made easily soluble in the aqueous solution 26 containing the RELACS™ material 6 by means of the water solubilization process made up of the adsorption process and the light irradiation process as described in the second embodiment with reference to FIGS. 6, 7A, and 7B. This is shown as step 31 (S-31) in a flowchart in FIG. 12.

Subsequently, as shown in FIGS. 12 and 13, a step similar to step 8 (S-8) according to the second embodiment is carried out to provide the aqueous solution containing the RELACS™ material 6 on the water-solubilized front surface of the first resist pattern 23 (resist film 22) and inside the first hole pattern 23a. Thus, the water-solubilized residue 22a in the first hole pattern 23a is dissolved in the aqueous solution 26 and washed away (etched).

Then, although not shown in the drawings, the aqueous solution 26 not formed into a RELACS™ film 28 is removed from inside the first hole pattern 23a and from the front surface of the first resist pattern 23 as is the case with to steps 9 (S-9) and 10 (S-10) according to the second embodiment. At this time, the residue 22a dissolved in the aqueous solution 26 is removed from inside the first hole pattern 23a together with the aqueous solution 26 not formed in the RELACS™ film 28. Thus, as is the case with the second embodiment, the RELACS™ film 28 is selectively left on the edge of the bottom surface of the first hole pattern 23a and over the inner side surfaces of the first hole pattern 23a to form a second hole pattern of diameter about 30 nm. The main steps of the pattern forming method according to the present embodiment are thus completed.

Then, although not shown in the drawings, steps similar to those described in the first embodiment with reference to FIGS. 4B and 5A to 5C are carried out to form, inside the interlayer insulating film 2, the fine contact plug 12 covered with the barrier metal film on the side surfaces and bottom surface and having a diameter of about 30 nm. The main steps of the electronic device manufacturing method according to the present embodiment are thus completed.

As described above, the fourth embodiment can exert effects similar to those of the first to third second embodiments, described above. Furthermore, the aqueous solution 26 containing the RELACS™ material 6 is also used as a wash fluid for removing the residue 22a from inside the first hole pattern 23a. The present embodiment can thus reduce the number of required pattern forming steps and electronic device manufacturing steps compared to the second embodiment, for simplification. This enables an increase in the efficiency of the pattern forming steps and electronic device manufacturing steps and a further reduction in the costs of the pattern forming steps and electronic device manufacturing steps.

### Fifth Embodiment

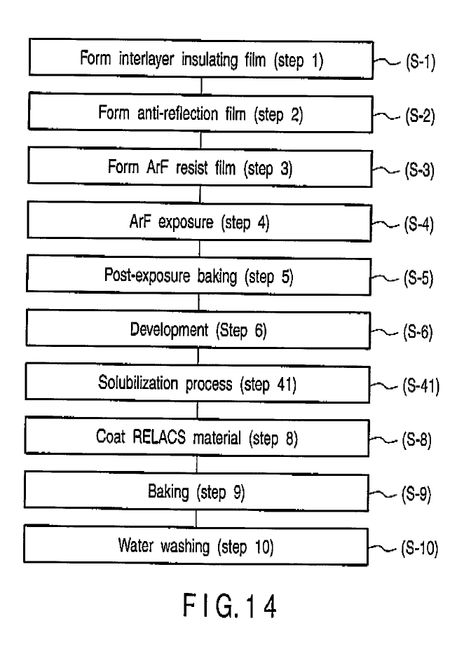

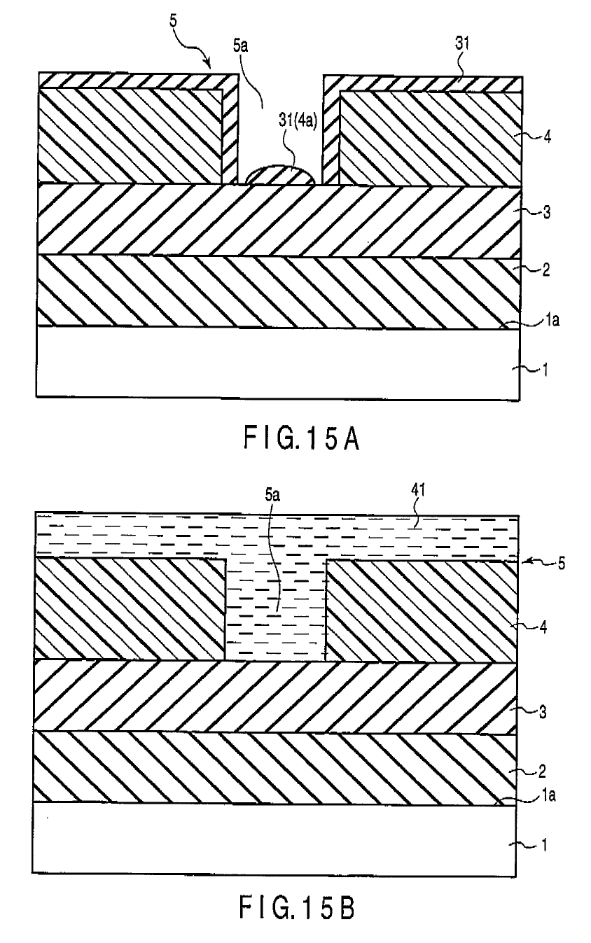

Now, a pattern forming method according to a fifth embodiment of the present invention will be described with reference to FIGS. 14, 15A, and 15B. The same components of the fifth embodiment as those of the first to third embodiments are denoted by the same reference numerals and will not be described in detail. The present embodiment is substantially similar to the third embodiment except that an alkaline solution containing the RELACS™ material is used as a wash fluid (etchant) for removing the residue. The fifth embodiment will be specifically described below.

First, as shown in FIGS. 14 and 15A, the first resist pattern 5 including the first hole pattern 5a with a diameter of about 100 nm is formed on the resist film 4 provided on the front surface 1a of the semiconductor substrate 1 as is the case with steps 1 (S-1) to 6 (S-6) according to the third embodiment. Although not shown in the drawings, the unwanted resist film 4a remained inside the first hole pattern 5a as a residue.

Subsequently, the solubilization process (water solubilization process) is carried out on the front layer portion of the first resist pattern 5 and the entire residue 4a to make the front surface of the resist film 4 easily soluble in an alkaline solution 41 containing the RELACS™ material 6. In this case, the front surface of the resist film 4 is made easily soluble in the alkaline solution containing the RELACS™ material 6 by carrying out the solubilization process made up of the light irradiation process as described in the third embodiment with reference to FIGS. 10 and 11A. This is shown as step 41 (S-41) in a flowchart in FIG. 14.

Then, as shown in FIGS. 14 and 15A, as is the case with step 8 (S-8) according to the third embodiment, the alkaline solution containing the RELACS™ material 6 is provided on the solubilized front surface of the first resist pattern 5 (resist film 4) and inside the first hole pattern 5a. Thus, the solubilized residue 31 (4a) in the first hole pattern 23a is dissolved in the aqueous solution 26 and washed away (etched).

Then, although not shown in the drawings, the alkaline solution 41 not formed into the RELACS™ film 7 is removed from inside the first hole pattern 5a and from the front surface of the first resist pattern 5 as is the case with to steps 9 (S-9) and 10 (S-10) according to the third embodiment. At this time, the residue 31 (4a) dissolved in the alkaline solution 41 is removed from inside the first hole pattern 5a together with the alkaline solution 26 not formed in the RELACS™ film 7. Thus, as is the case with the third embodiment, the RELACS™ film 7 is selectively left on the edge of the bottom surface of the first hole pattern 5a and over the inner side surfaces of the first hole pattern 5a to form a second hole pattern of diameter about 80 nm. The main steps of the pattern forming method according to the present embodiment are thus completed.

Then, although not shown in the drawings, steps similar to those described in the first embodiment with reference to FIGS. 4B and 5A to 5C are carried out to form, inside the interlayer insulating film 2, the fine contact plug 12 covered with the barrier metal film on the side surfaces and bottom surface and having a diameter of about 80 nm. The main steps of the electronic device manufacturing method according to the present embodiment are thus completed.

As described above, the fifth embodiment can exert effects similar to those of the first to fourth second embodiments, described above. Furthermore, the alkaline solution 41 containing the RELACS™ material 6 is also used as a wash fluid for removing the residue 31 (4a) from inside the first hole pattern 5a. The present embodiment can thus reduce the number of required pattern forming steps and electronic device manufacturing steps compared to the third embodiment, for simplification. This enables an increase in the efficiency of the pattern forming steps and electronic device manufacturing steps and a further reduction in the costs of the pattern forming steps and electronic device manufacturing steps.

### Sixth Embodiment

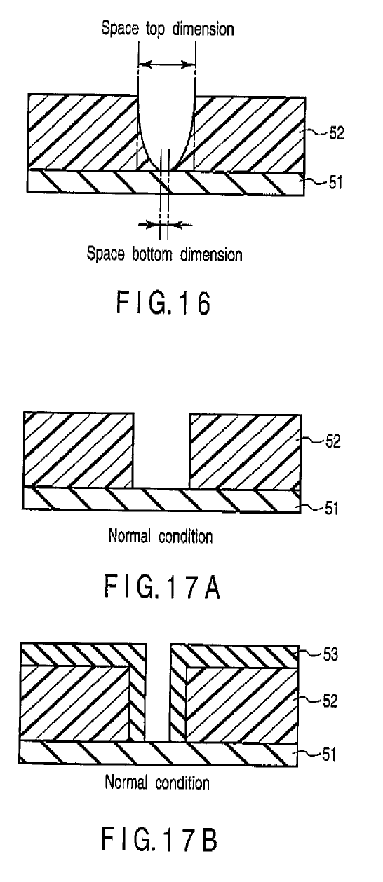

Now, a sixth embodiment of the present invention will be described with reference to FIGS. 16, 17A, 17B, 18A, 18B, 19A, 19B, and 20.

The sixth embodiment corresponds to the manufacturing steps according to the above-described first to fifth embodiments in which if the width (space top dimension) of a bottom space of the resist pattern (reference pattern) is significantly smaller than that (space bottom dimension) of a top space of the resist pattern, indicating the possibility that the resist pattern is unopened, the pattern is corrected so as to make the width of the bottom space of the resist pattern closer to that of the top space of the resist pattern.

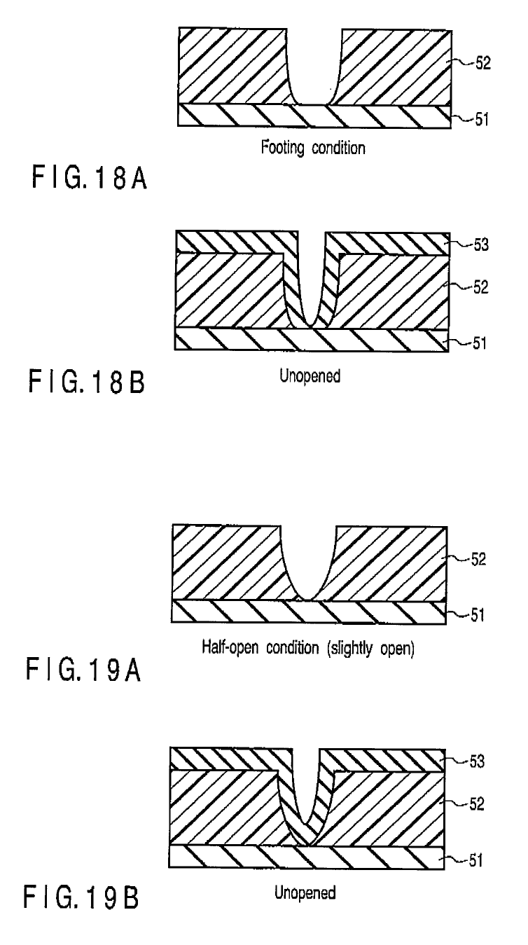

For micropatterns with sizes close to the critical resolution, a resist pattern 52 that is otherwise open on a processing target film 51 as shown in FIG. 17A, may be in a footing condition as shown in FIG. 18A or may be half-open as shown in FIG. 19A owing to a slight fluctuation in a lithography process (for example, a variation in exposure amount or baking temperature, or a variation in rinse conditions during development). In this condition, when RELACS or 2300MOTIF, described above, is applied to form a deposited film 53 and to remove a space deposited film as shown in FIG. 17B, the pattern may be unopened as shown in FIGS. 18B and 19B.

Thus, if the resist pattern is likely to be unopened, then after the resist pattern is formed as described above, the pattern is corrected so as to make the bottom space width closer to the top space width.

Now, the pattern correction will be specifically described in detail.

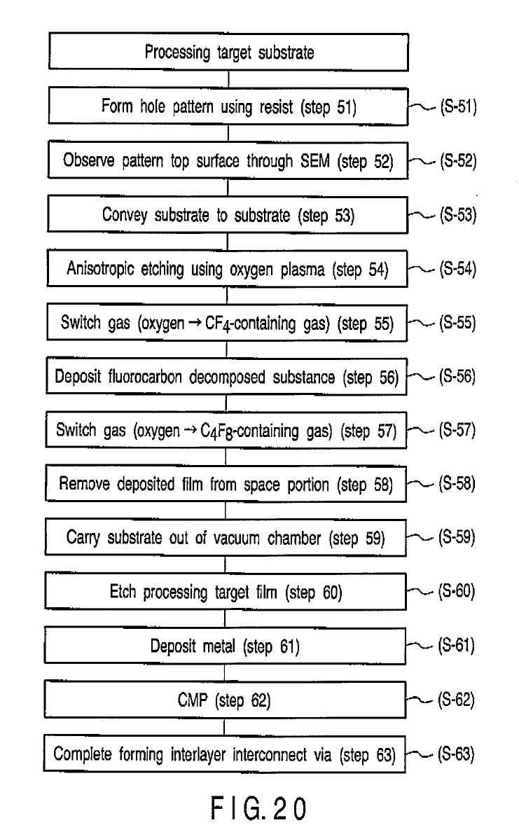

FIG. 20 shows a process flow according to the sixth embodiment. First, a processing target substrate is prepared. Then, a resist film is formed on a processing target film of the substrate. Hole patterns through which interconnect vias of diameter 100 nm are formed are formed by exposure and development (S-51). The present inventors observed the entire front surface of the substrate from above for pattern shapes using SEM (S-52) to find that the width of the bottom space of some of the patterns was very small.

Thus, the substrate is conveyed to a vacuum chamber (S-53). Oxygen gas is introduced into the vacuum chamber to produce oxygen plasma for anisotropic etching (S-54). The resist remaining at the bottom of the pattern is mainly due to inappropriate rinsing during development. The remaining resist is a film having more voids than the resist pattern, that is, the reference pattern. Thus, the bottom space width can be increased so as to be substantially equal to the top space width with the pattern shape almost maintained by optimizing control factors including acceleration voltage, the anisotropy of electric fields, magnetic fields, and the like, and processing speed.

Then, a gas species in the same chamber in which the substrate is placed is switched to a CF₄-containing fluorocarbon gas (S-55). Processing is carried out under conditions under which fluorocarbon is decomposed and deposited on the resist pattern, to form a deposited film of fluorocarbon on the front surface of the resist pattern (S-56). Subsequently, the gas species is switched to oxygen and fluorocarbon (for example, C₄F₈-containing gas) (S-57). The deposited film in the reference pattern space portion is further etched to expose the processing target film (S-58).

Subsequently, the substrate is carried out of the vacuum chamber (S-59). The pattern newly formed had a diameter of 75 nm, which was smaller than the initial pattern by 25 nm. The processing target film is etched through the new pattern as a mask (S-60). Metal is then deposited on the processing target film (S-61). Excess metal is removed by CMP (S-62). An interconnect via is formed (S-63).

According to the above-described manufacturing method, if the width of the bottom space of the resist pattern is significantly smaller than that of the top space of the resist pattern, indicating the possibility that the resist pattern is unopened, the pattern is corrected so as to make the width of the bottom space of the resist pattern closer to that of the top space of the resist pattern. This enables a sharp reduction in the number of defects, that is, unopened patterns compared to the case in which the present invention is not applied. The present inventors confirmed through defect inspections that the number of defects, that is, unopened patterns can be reduced to at most one tenth.

In the present embodiment, the formation of fine vias has been described by way of example. However, the present embodiment is also applicable to the formation of fine buried interconnect (microgroove) patterns. Furthermore, the present embodiment is applicable to a pattern type having a size close to the critical resolution and which is difficult to provide a sufficient process margin, to improve miniaturization or to a pattern with a size offering a sufficient margin for the resolution, to improve manufacturing yield.

Furthermore, microhole patterns equivalent to those described above can be formed by the following steps. A hard mask is pre-formed under a resist film. The resist is patterned and the substrate is conveyed to the vacuum chamber. The bottom width of the resist is subjected to an opening process, and the hard mask is processed. A deposited film is then formed on the hard mask pattern using fluorocarbon-containing gas. The deposited film is removed from recess portions of the hard mask. The processing target mask is further processed.

As described above, the pattern forming method according to the sixth embodiment of the present invention includes a step of preparing a processing target substrate, a bottom space width increasing step of increasing the width of a bottom space of a reference pattern so as to make the width of the bottom space of the reference pattern closer to that of a top space of the reference pattern, and a side wall film increasing step. The side wall film increasing step includes a deposition step of forming a deposited film on a front surface of the reference pattern and a step of removing the deposited film on the bottom space of the reference pattern by anisotropic etching to expose a part of the bottom space which is narrower than the bottom space of the reference pattern.

Desirably, the side wall film increasing step is carried out plural times. Furthermore, the anisotropic etching is desirably controlled such that the deposited film formed on the front surface of the reference pattern so that the etching rate for the deposited film on the bottom space of the reference pattern is higher than that for the deposited film on the side wall portions of the reference pattern.

If the reference pattern needs to prevent reflection, an anti-reflection film is formed on the processing target film, with the resist film formed on the anti-reflection film. Then, the exposure apparatus is used to form a latent image on the resist on the basis of an exposure original plate or beam scanning. A step of amplifying the latent image, such as heating, is carried out if required. Moreover, a development step and a rinsing step are carried out to produce the pattern.

Alternatively, the reference pattern may be formed of an oxide film, a nitride film, or an organic film with a high carbon content obtained by processing the processing target film through the above-described resist pattern as a mask.

For the opening of the bottom space width, if the pattern is degraded by a variation in process conditions or the like, the possible cause is the low intensity of exposure light or insufficient reaction in spite of the exposure of the opening. Thus, corrections are performed such that the bottom space width is increased with an etching selection ratio appropriately set by balancing gas conditions or changing the acceleration voltage. If the object is the resist, the corrections can be achieved by changing the activity of the alkaline solution (for example, changing the concentration of the alkaline solution or adding functional water to the alkaline solution). If the object is an oxide film, the corrections can be achieved by using fluoric acid or the like to change the concentration of the alkaline solution to increase the bottom space width.

The sixth embodiment can provide a method of manufacturing a semiconductor device which method forms a fine via or trench in the processing target substrate using a fine hole or groove formed by the pattern forming method.

The sixth embodiment can also provide a method of manufacturing a semiconductor device which method forms fine interconnects using a side wall deposited film pattern formed by the pattern forming method.

The pattern forming method according to the present invention is not limited to the above-described first to sixth embodiments. For example, the first to sixth embodiments are carried out using the RELACS™ material disclosed in the Web feature article “Semiconductor 0.1-part hole pattern forming technique RELACS” presented by Mitsubishi Electric Corporation. However, the RELACS™ material need not necessarily be used. The results of the present inventors' experiments show that for example, such a common coating film as does not interact with the resist pattern may be used instead of the RELACS™ material as follows: the coating film is provided in the first hole pattern 5a or 23a and the first resist pattern 5 or 23 is heated, enabling a reduction in the diameter of the first hole pattern 5a or 23a with the resist impregnated with the coating film. The results of the experiments also show that this technique can exert effects similar to those of the first to sixth embodiments.

Furthermore, in the description of the first to sixth embodiments, the technique according to these embodiments forms the first hole pattern 5a or 23a with the size close to the critical resolution of the exposure apparatus as the space portion 5 or 23a of the first resist pattern 5 or 23. However, the present invention is not limited to this aspect. The results of the present inventors' experiments show that the technique according to the first to sixth embodiments is also applicable to an interconnect pattern formed by applying this technique to reduce the space width of a space pattern formed under a common design rule and then filling an interconnect material into the interlayer insulating film; in this case, the defect density of the interconnect pattern can be sharply reduced.

Moreover, the diameter of the first hole pattern 5a or 23a and the diameter of the second hole pattern 8a, on which the pattern forming method according to the embodiments of the present invention is effective, is not limited to the above-described dimensions. The pattern forming method according to the present invention can exert effects similar to those described above provided that for example, the dimension of the diameter of the hole pattern to be formed is at most about 100 nm. Furthermore, effects similar to those described above can be exerted provided that for example, the hole pattern to be formed has an aspect ratio of at least about 1. Alternatively, the pattern forming method according to the embodiments of the present invention can exert effects similar to those described above provided that for example, a space pattern of a line-and-space pattern (L/S pattern) to be formed has a width of at most about 50 nm. Furthermore, the pattern forming method according to the embodiments of the present invention can exert effects similar to those described above provided that for example, a hole pattern is such that a space pattern of a line-and-space pattern (L/S pattern) to be formed has an aspect ratio of at least 2.

As described above, according to one aspect of this invention, a pattern forming method enabling fine patterns to be formed can be provided.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern forming method comprising:
patterning a resist film provided on one major surface of a process target substrate to form a resist pattern; and
forming a moisture-containing film on a front surface of the process target substrate in a space portion of the resist pattern, irradiating the moisture-containing film with light, and supplying a liquid containing moisture to the moisture-containing film.

2. The pattern forming method according to claim 1, wherein the process target film includes a semiconductor substrate, an interlayer insulating film formed on one major surface of the semiconductor substrate, and an anti-reflection film formed on the interlayer insulating film.

3. The pattern forming method according to claim 1, wherein the process target film includes a semiconductor substrate, an interlayer insulating film formed on one major surface of the semiconductor substrate, and a hard mask layer formed on the interlayer insulating film.

4. The pattern forming method according to claim 1, wherein forming the resist pattern includes forming a resist film on the process target substrate, exposing the resist film to form a latent image, and forming a hole pattern in the resist film.

5. The pattern forming method according to claim 4, further comprising removing a residue remaining in the hole pattern.

6. The pattern forming method according to claim 5, wherein removing the residue includes carrying out a solubilization process on the resist pattern so that the resist film is easily soluble in a liquid for removing the residue remaining in the hole pattern and using the liquid to carry out a process of removing the residue.

7. The pattern forming method according to claim 1, wherein irradiating the moisture-containing film with light and supplying the liquid containing the moisture to the moisture-containing film comprises altering a front layer portion of the resist pattern to a hydrophilicized layer.

8. The pattern forming method according to claim 7, wherein the light has a wavelength of less than 200 nm, and moisture adsorbed on the resist pattern is radicalized to add a hydroxyl group to a front surface of the resist pattern.

9. The pattern forming method according to claim 1, further comprising, if after formation of the resist pattern, a bottom dimension of the space portion of the resist pattern is smaller than a top dimension of the space portion, correcting the pattern so as to make a bottom space width closer to a top space width.

10. The pattern forming method according to claim 9, wherein correcting the pattern comprises increasing the bottom space width so as to make the bottom space width closer to the top space width, and increasing film thickness of a side wall, and
increasing the film thickness of the side wall comprises forming a deposited film on the front surface of the resist pattern, and subsequently to the formation of the deposited film, removing the deposited film from a front surface of the bottom space of the resist pattern by anisotropic etching to expose a part of the bottom space which is narrower than the bottom space.

11. A pattern forming method comprising:
patterning a resist film provided on one major surface of a process target substrate to form a resist pattern;
carrying out a solubilization process on the resist film remaining in a space portion of the resist pattern;
supplying a liquid for removing the resist film to remove the resist film remaining in the space portion of the resist pattern;
introducing a material for a pattern forming complementary film which is formed into a film through interaction with the resist film, into the space portion of the resist pattern;
allowing the material for the pattern forming complementary film to interact with the resist film to selectively form the pattern forming complementary film on inner side surfaces of the space portion; and
removing a part of the material for the pattern forming complementary film which has not been formed into a film, from inside the space portion with the remaining part of the pattern forming complementary film left in the space portion to expose a part of a bottom surface of the space portion.

12. The pattern forming method according to claim 11, wherein the interaction between the material for the pattern forming complementary film and the resist film comprises carrying out a baking process to form a crosslinking mixing layer between the resist film and the material for the pattern forming complementary film.

13. The pattern forming method according to claim 11, further comprising, after partly exposing the bottom surface of the space portion, processing the process target substrate using the resist pattern and the remaining part of the pattern forming complementary film as a mask.

14. The pattern forming method according to claim 11, further comprising, if after formation of the resist pattern, a bottom dimension of the space portion of the resist pattern is smaller than a top dimension of the space portion, correcting the pattern so as to make a bottom space width closer to a top space width.

15. The pattern forming method according to claim 14, wherein correcting the pattern comprises increasing the bottom space width so as to make the bottom space width closer to the top space width, and increasing film thickness of a side wall, and
increasing the film thickness of the side wall comprises forming a deposited film on the front surface of the resist pattern, and subsequently to the formation of the deposited film, removing the deposited film from a front surface of the bottom space of the resist pattern by anisotropic etching to expose a part of the bottom space which is narrower than the bottom space.

16. A pattern forming method comprising:
patterning a resist film provided on one major surface of a process target substrate to form a resist pattern;
carrying out a solubilization process on the resist film remaining in a space portion of the resist pattern;
supplying a liquid for removing the resist film, the liquid containing a material for a pattern forming complementary film which is formed into a film through interaction with the resist film;
allowing the material for the pattern forming complementary film to interact with the resist film to selectively form the pattern forming complementary film on inner side surfaces of the space portion; and
removing a part of the material for the pattern forming complementary film which has not been formed into a film, from inside the space portion with the remaining part of the pattern forming complementary film left in the space portion to expose a part of a bottom surface of the space portion.

17. The pattern forming method according to claim 16, wherein the interaction between the material for the pattern forming complementary film and the resist film comprises carrying out a baking process to form a crosslinking mixing layer between the resist film and the material for the pattern forming complementary film.

18. The pattern forming method according to claim 16, further comprising, after partly exposing the bottom surface of the space portion, processing the process target substrate using the resist pattern and the remaining part of the pattern forming complementary film as a mask.

19. The pattern forming method according to claim 16, further comprising, if after formation of the resist pattern, a bottom dimension of the space portion of the resist pattern is smaller than a top dimension of the space portion, correcting the pattern so as to make a bottom space width closer to a top space width.

20. The pattern forming method according to claim 19, wherein correcting the pattern comprises increasing the bottom space width so as to make the bottom space width closer to the top space width, and increasing film thickness of a side wall, and
increasing the film thickness of the side wall comprises forming a deposited film on the front surface of the resist pattern, and subsequently to the formation of the deposited film, removing the deposited film from a front surface of the bottom space of the resist pattern by anisotropic etching to expose a part of the bottom space which is narrower than the bottom space.
